(19) United States
(12) Patent Application Publication
(10) Pub. No.: US 2026/0144131 A1
(43) Pub. Date: May 21, 2026

(54) SEMICONDUCTOR PACKAGE WITH STACKED SEMICONDUCTOR DIES

(71) Applicant: SEMICONDUCTOR COMPONENTS INDUSTRIES, LLC, Scottsdale, AZ (US)

(72) Inventors: Gareth Pryce WEALE, New Hamburg (CA); Ravinder BILKHU, Oakville (CA); David Allan ROY, Port Colborne (CA); John ARCHER, Mississauga (CA)

(73) Assignee: SEMICONDUCTOR COMPONENTS INDUSTRIES, LLC, Scottsdale, AZ (US)

(21) Appl. No.: 19/393,217

(22) Filed: Nov. 18, 2025

Related U.S. Application Data
(60) Provisional application No. 63/723,402, filed on Nov. 21, 2024.

(51) Int. Cl. H01L 23/00; G02B 6/12; H01L 23/31; H01L 25/065

(52) U.S. Cl. CPC H10W 74/131; H10W 90/00; G02B 6/12; H10W 72/242

(57) ABSTRACT

In a general aspect, a semiconductor package includes a first semiconductor die. The semiconductor package includes a second semiconductor die coupled to the first semiconductor die. The semiconductor package includes a plurality of first pillars coupled to the first semiconductor die, each of the first pillars having a first height. The semiconductor package includes a plurality of second pillars coupled to the second semiconductor die, each of the second pillars having a second height that is less than the first height. The semiconductor package includes a mold layer that encapsulates a surface of the first semiconductor die, the second semiconductor die, the plurality of first pillars, and the plurality of second pillars. Top surfaces of the first pillars and top surfaces of the second pillars are exposed at a surface of the mold layer and are substantially coplanar with the surface of the mold layer.

### CROSS-REFERENCE TO RELATED APPLICATIONS

This application claims the benefit of U.S. Provisional Application No. 63/723,402, filed on Nov. 21, 2024, which is hereby incorporated by reference in its entirety.

### TECHNICAL FIELD

This description relates to semiconductor packages and, more particularly, to a semiconductor package with stacked semiconductor dies.

### BACKGROUND

The field of semiconductor packaging continues to advance to meet the growing need for higher performance, greater integration density, and reduced form factors, even as shrinking device geometries and lower operating voltages make monolithic integration increasingly difficult. Consequently, the industry is shifting toward multi-chip architectures in which multiple semiconductor dies are integrated in the same semiconductor package.

### SUMMARY

In a general aspect, a semiconductor package includes a first semiconductor die. The semiconductor package includes a second semiconductor die coupled to the first semiconductor die. The semiconductor package includes a plurality of first pillars coupled to the first semiconductor die, each of the first pillars having a first height. The semiconductor package includes a plurality of second pillars coupled to the second semiconductor die, each of the second pillars having a second height that is less than the first height. The semiconductor package includes a mold layer that encapsulates a surface of the first semiconductor die, the second semiconductor die, the plurality of first pillars, and the plurality of second pillars. Top surfaces of the first pillars and top surfaces of the second pillars are exposed at a surface of the mold layer and are substantially coplanar with the surface of the mold layer.

In some aspects, the plurality of first pillars at least partially surrounds the second semiconductor die.

In some aspects, the plurality of first pillars and the plurality of second pillars include a metal or a metal alloy.

In some aspects, the semiconductor package further includes a patterned metal layer disposed on the surface of the mold layer. The patterned metal layer is electrically coupled to the top surfaces of the first pillars and the top surfaces of the second pillars.

In some aspects, the semiconductor package further includes a plurality of external interconnect structures disposed on the patterned metal layer.

In some aspects, the patterned metal layer electrically couples at least one of the first pillars to at least one of the second pillars.

In some aspects, the plurality of first pillars and the plurality of second pillars include an optically transmissive material.

In some aspects, the first semiconductor die includes a plurality of first optical interfaces, and the plurality of first pillars are disposed on the first optical interfaces. The second semiconductor die further includes a plurality of second optical interfaces, and the plurality of second pillars are disposed on the second optical interfaces.

In some aspects, the semiconductor package further includes an optical waveguide disposed on the surface of the mold layer. The optical waveguide optically couples at least one first pillar to at least one second pillar.

In some aspects, the semiconductor package further includes a third semiconductor die coupled to the second semiconductor die. The semiconductor package includes a plurality of third pillars having a third height that is less than the second height. The mold layer encapsulates the third semiconductor die and the plurality of third pillars. Top surfaces of the third pillars are exposed at and substantially coplanar with the surface of the mold layer.

In some aspects, the semiconductor package includes a third semiconductor die coupled to the first semiconductor die and positioned lateral to the second semiconductor die. The package includes a plurality of third pillars having a third height that is less than the first height. The mold layer encapsulates the third semiconductor die and the plurality of third pillars. Top surfaces of the third pillars are exposed at and substantially coplanar with the surface of the mold layer.

In a general aspect, a semiconductor package includes a first semiconductor die having a first substrate material. The semiconductor package includes a second semiconductor die coupled to the first semiconductor die, the second semiconductor die having a second substrate material different from the first substrate material. The semiconductor package includes a plurality of pillars coupled to the first semiconductor die, the pillars having a first height. The semiconductor package includes a plurality of interconnects coupled to the second semiconductor die. The semiconductor package includes a mold layer that encapsulates a surface of the first semiconductor die, the second semiconductor die, the plurality of pillars, and the plurality of interconnects. Top surfaces of the pillars and top surfaces of the interconnects are coplanar and exposed at a surface of the mold layer.

In some aspects, the first substrate material is silicon, silicon carbide, gallium nitride, or gallium arsenide, and the second substrate material is silicon, silicon carbide, gallium nitride, or gallium arsenide.

In some aspects, the interconnects include conductive pillars. In some other aspects, the interconnects include solder structures.

In some aspects, at least one of the first semiconductor die and the second semiconductor die includes a power device die.

In a general aspect, a method of fabricating a semiconductor package includes providing a semiconductor wafer having a plurality of first pillars of a first height formed on a surface of the wafer. The method includes mounting a semiconductor die on the surface of the wafer, where a plurality of second pillars of a second height less than the first height are formed on the semiconductor die. The method includes forming a mold layer over the wafer surface, the semiconductor die, the first pillars, and the second pillars. The method includes planarizing the mold layer to expose top surfaces of the first pillars and top surfaces of the second pillars.

In some aspects, the method further includes forming an interconnect layer on the planarized surface of the mold layer. The interconnect layer provides either electrical coupling or optical coupling between at least one of the first pillars and at least one of the second pillars.

In some aspects, the method includes, before forming the mold layer, partially sawing the semiconductor wafer along predefined dicing lanes.

In some aspects, the method includes thinning the semiconductor wafer from its back surface until grooves formed by the partial sawing are exposed.

The details of one or more implementations are set forth in the accompanying drawings and the description below. Other features will be apparent from the description and drawings, and from the claims.

### BRIEF DESCRIPTION OF THE DRAWINGS

FIG. 1 illustrates a cross-sectional view of an example semiconductor package in

accordance with at least one embodiment of the present disclosure.

FIG. 2A illustrates an isometric view of an example semiconductor package in accordance with at least one embodiment of the present disclosure.

FIG. 2B illustrates a plan view of an example semiconductor package in accordance with at least one embodiment of the present disclosure.

FIG. 3 illustrates a cross-sectional view of another implementation of an example semiconductor package in accordance with at least one embodiment of the present disclosure.

FIG. 4 illustrates a cross-sectional view of another implementation of an example semiconductor package in accordance with at least one embodiment of the present disclosure.

FIGS. 5A-5D illustrate cross-sectional views of an example process of fabricating an example semiconductor die in accordance with at least one embodiment of the present disclosure.

FIGS. 6A-6I illustrate cross-sectional views of an example process of fabricating an example semiconductor package in accordance with at least one embodiment of the present disclosure.

FIGS. 7A-7I illustrate cross-sectional views of an example process of fabricating another example semiconductor package in accordance with at least one embodiment of the present disclosure.

FIGS. 8A-8H illustrate cross-sectional views of an example process of fabricating another example semiconductor package in accordance with at least one embodiment of the present disclosure.

FIG. 9 is a flow chart illustrating an example method for fabricating a semiconductor package in accordance with at least one embodiment of the present disclosure.

In the various drawings, which are not necessarily drawn to scale, like reference symbols may indicate like and/or similar components (elements, structures, etc.) in different views and/or different implementations. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are repeated for context and ease of cross reference between related views. Also, not all like elements in the drawings may be specifically referenced with a reference symbol when multiple instances of an element are illustrated.

### DETAILED DESCRIPTION

The field of semiconductor packaging continues to evolve to address the increasing

demands of modern electronic systems for higher performance, greater integration density, and reduced form factor. The drive to integrate all system functionality onto a single monolithic chip has become increasingly challenging as device geometries shrink, operating voltages decrease, and system architectures require diverse interfaces to external components. As a result, the industry has moved toward a chiplet-based and multi-chip integration paradigm, wherein different system modules may be fabricated using optimized process technologies and subsequently combined into a heterogeneous assembly tailored to the functional and cost requirements of the end system.

Advanced packaging platforms, including three-dimensional integrated circuits (3D ICs), system-in-package (SiP) architectures, and chiplet-based designs, have therefore become key enablers for heterogeneous integration. These technologies permit the combination of logic, memory, sensor, and power devices, often manufactured using different process nodes, materials, or wafer sizes, into compact functional units. However, multi-chip solutions must also overcome challenges related to volumetric efficiency, electrical performance, thermal management, and manufacturability.

One common approach has been to use wire bonds to connect the dies, which can be time-consuming and may limit the density of the package. Another approach has been to use through-silicon vias (TSVs) to connect the dies, which can provide higher density but may require complex and expensive manufacturing processes. In addition, TSVs can be prone to defects and may require additional processing steps to ensure reliability.

Fan-out wafer-level packaging (FOWLP) is another approach for heterogeneous integration. In conventional FOWLP processes, individual dies are placed on a carrier, encapsulated in a molding compound to form a reconstituted wafer, and interconnected through a redistribution layer (RDL). The RDL reroutes signals from fine-pitch die contacts to larger-pitch external terminals such as ball grid array (BGA) connections. Conventional FOWLP architectures present challenges when multiple dies are integrated, particularly in stacked or densely arranged configurations. Establishing die-to-die communication often requires complex routing through multi-level RDL structures, involving repeated dielectric deposition, lithographic patterning, and metallization steps. These multi-layer processes increase manufacturing cost and complexity, may reduce yield, and can adversely affect signal integrity. Additionally, achieving uniform planarity across a reconstituted wafer is difficult when dies of varying thickness are present, complicating reliable RDL formation.

Embodiments in accordance with the present disclosure address these challenges by providing a semiconductor package architecture and fabrication method that simplifies die-to-die interconnection in multi-chip assemblies. A technical solution involves forming pillars of varying heights on respective semiconductor dies prior to assembly. The dies are then arranged in a stacked configuration, such that top-level surfaces of the pillars on both dies are substantially coplanar, and encapsulated in a molding compound. A subsequent planarization process exposes the top surfaces of all pillars, creating a uniform, coplanar surface for interconnection or metallization that is independent of the underlying die topography. In some implementations, a patterned metal layer is formed on this planarized surface to directly interconnect the pillars of the different dies, thereby creating signal paths between the dies. Effectively, complex multi-level RDL structures can be avoided, which reduces manufacturing complexity and cost, improves production yield, and enhances electrical performance by providing shorter, direct signal paths.

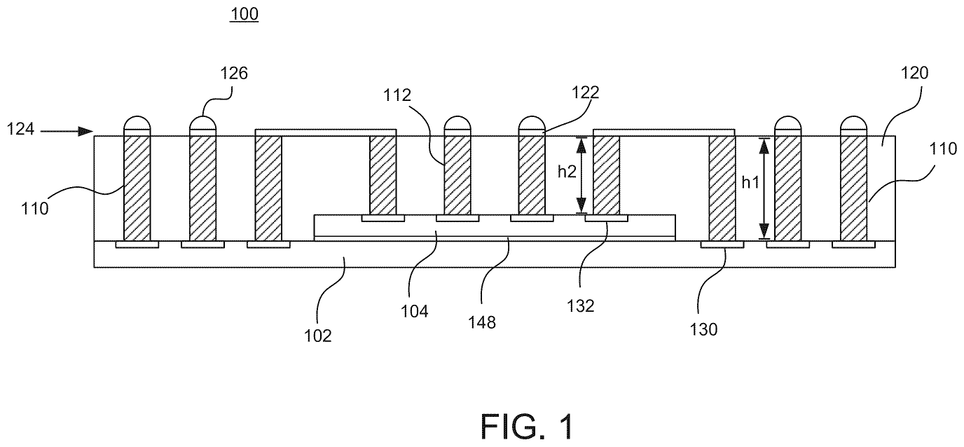

FIG. 1 illustrates a cross-sectional view of an example semiconductor package 100 in accordance with at least one embodiment of the present disclosure. In some implementations, the package 100 includes a lower semiconductor die 102 and an upper semiconductor die 104 mounted on a die attach region of the lower die 102. A first plurality of pillars 110 is coupled to the lower semiconductor die 102 and surrounds the upper semiconductor die 104, which is nested among them. A second plurality of pillars 112 is coupled to the upper semiconductor die 104. A mold layer 120 encapsulates the dies 102, 104 and the pillars 110, 112. A patterned metal layer 124 is disposed on the mold layer 120 and is electrically coupled to the pillars 110, 112. The package 100 also includes external interconnect structures 126 formed on the patterned metal layer 124.

In some implementations, the lower semiconductor die 102 includes one or more device regions configured to provide electronic functionality. In various examples, the device regions can implement a logic device such as a processor or controller die, a memory device such as a DRAM or NAND flash die, a sensor die, a power semiconductor die such as a MOSFET, IGBT, or diode, and so forth. The lower semiconductor die 102 includes contact pads 130 providing electrical connection to the device region. In some examples, the lower semiconductor die 102 comprises a silicon die, a silicon carbide die, a gallium nitride die, or a gallium arsenide die. In some implementations, the lower semiconductor die 102 has a thinned back surface.

In some implementations, the first plurality of pillars 110 are electrically coupled to the contact pads 130 of the lower semiconductor die 102. The pillars 110 have a height h2. In some examples, the pillar height h2 ranges from about 100 μm to 200 μm. The pillars 110 can have a desired cross-sectional geometry, such as a generally cylindrical shape, a tapered or frustoconical shape, or a rectangular, hexagonal, or other polygonal cross-section. In some implementations, the pillars 110 are metal pillars such as copper, aluminum, gold, tin, titanium, or other metal with similar electrical and mechanical properties. In other implementations, the pillars 110 are optically transmissive pillars.

In some implementations, the upper semiconductor die 104 includes one or more device regions configured to provide electronic functionality. In various examples, the device regions can implement a logic device such as a processor or controller die, a memory device such as a DRAM or NAND flash die, a sensor die, a power semiconductor die such as a MOSFET, IGBT, or diode, and so forth. The upper semiconductor die 104 includes contact pads 132 providing electrical connection to its device region. In some examples, the upper semiconductor die 104 comprises a silicon die, a silicon carbide die, a gallium nitride die, or a gallium arsenide die.

In some implementations, the second plurality of pillars 112 are electrically coupled to the contact pads 132 of the upper semiconductor die 104. The pillars 112 have a height h1 that is less than the height h2 of pillars 110. In some examples, the pillar height h1 ranges from about 50 μm to 100 μm. The pillars 112 can have a cross-sectional geometry and composition similar to the pillars 110. In some implementations, the pillars 112 are metal pillars such as copper, aluminum, gold, tin, titanium, or other metal with similar electrical and mechanical properties. In other implementations, the pillars 112 are optically transmissive pillars.

In some implementations, the mold layer 120 encapsulates the lower semiconductor die 102, the upper semiconductor die 104, the first plurality of pillars 110, and the second plurality of pillars 112. The mold layer 120 provides mechanical protection, environmental sealing, and structural support for the package 100. The mold layer 120 has a planar upper surface that is substantially coplanar with top surfaces of the pillars 110 and the pillars 112. In some examples, the mold layer 120 includes an epoxy molding compound (EMC) filled with silica or alumina particles. In other examples, the mold layer 120 includes a silicone, polyimide, or other dielectric material.

In some implementations, the patterned metal layer 124 is disposed on the planar upper surface of the mold layer 120. The patterned metal layer 124 includes a plurality of metal pads 122 and traces that electrically connect the exposed top surfaces of pillars 110 and pillars 112. In some examples, the patterned metal layer 124 comprises a conductive material, such as copper, nickel, gold, aluminum, or combinations thereof. In some implementations, the patterned metal layer 124 is a single layer of metal routing that connects the pillars 112 of the upper semiconductor die 104 to the pillars 110 of the lower semiconductor die 102.

In some implementations, the external interconnect structures 126 are formed on the metal pads 122. The interconnect structures 126 are configured for attaching the package 100 to an external component, such as a package substrate or a printed circuit board. In some examples, the interconnect structures 126 are microbumps or ball grid array (BGA) solder balls. In some examples, the interconnect structures 126 comprise a solder material such as tin, tin-silver, or tin-copper. In some implementations, the interconnect structures 126 form microbumps having diameters less than about 50 μm. In other implementations, the interconnect structures 126 form BGA solder balls having diameters between approximately 100 μm and 500 μm.

In some implementations, the upper semiconductor die 104 is coupled to the lower semiconductor die 102 via a bonding layer 148. For example, the bonding layer 148 includes bonding material configured to provide mechanical and, in some cases, electrical connection. In some examples, the bonding material includes a solder, such as tin, tin-silver, or tin-copper, that is reflowed to form a metallurgical joint. In other examples, the bonding material comprises an adhesive layer. In some examples, the adhesive is a conductive adhesive, such as a silver-filled or copper-filled epoxy paste, an anisotropic conductive film (ACF), or an anisotropic conductive paste (ACP), providing both mechanical and electrical coupling. In some examples, the bonding material is sinter material. In other examples, the adhesive is a non-conductive adhesive, such as an epoxy, polyimide, or silicone-based film or paste.

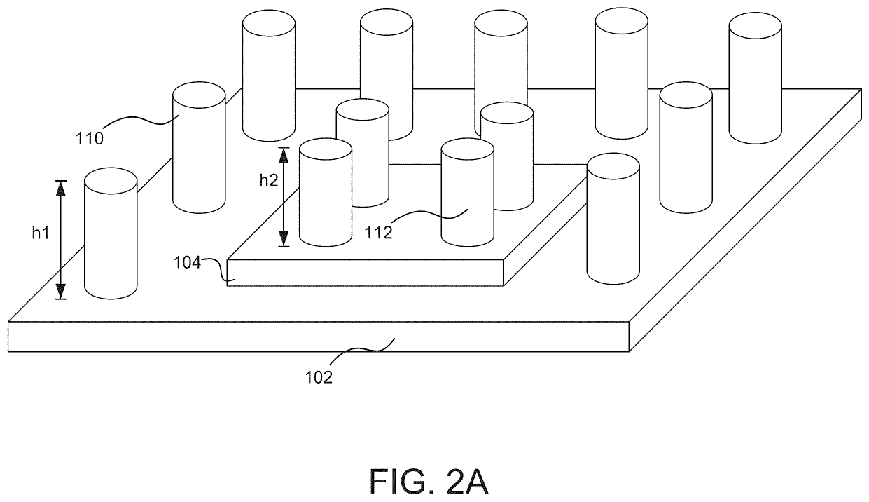

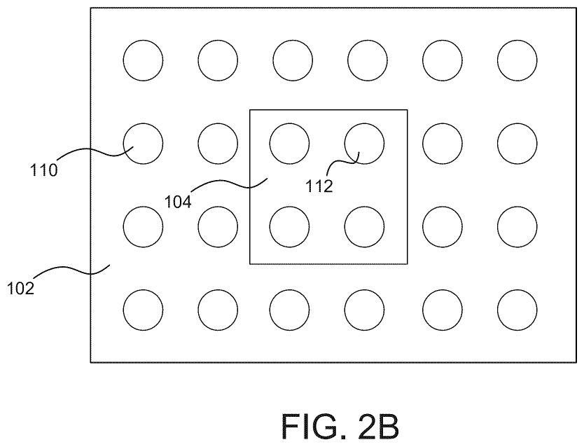

For further illustration, FIG. 2A illustrates a partial isometric view of example semiconductor package such as the semiconductor package 100 of FIG. 1. FIG. 2B illustrates a partial top view of example semiconductor package such as the semiconductor package 100 of FIG. 1.

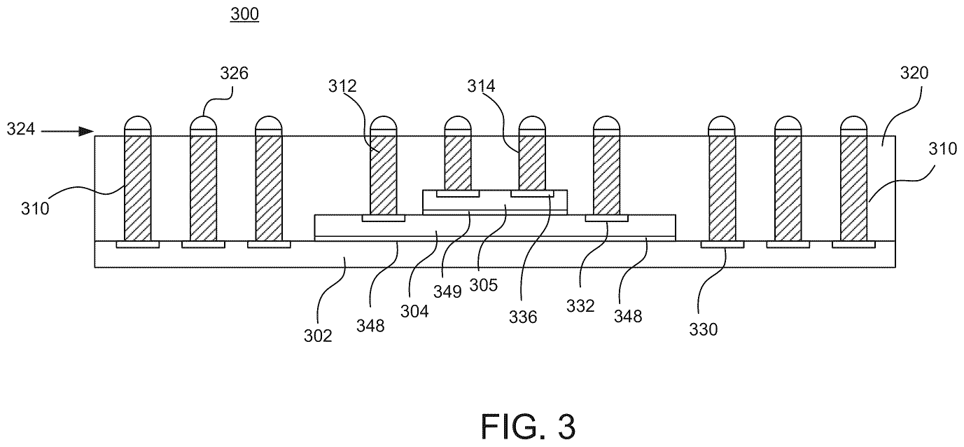

FIG. 3 illustrates a cross-sectional view of another example semiconductor package 300 in accordance with at least one embodiment of the present disclosure. In some implementations, the package 300 includes a three-die stack comprising a first semiconductor die 302, a second semiconductor die 304, and a third semiconductor die 305, each of which can be similar in construction and characteristics to dies 102, 104 of FIG. 1. The second die 304 is mounted on the first die 302, and the third die 305 is mounted on the second die 304. A first plurality of pillars 310 is coupled to contact pads 330 of the first die 302, a second plurality of pillars 312 is coupled to contact pads 332 the second die 304, and a third plurality of pillars 314 is coupled to contact pads 336 of the third die 305. A mold layer 320 encapsulates all three dies and their respective pillars. The top surfaces of the pillars 310, 312, and 314 are exposed at and are substantially coplanar with a planar upper surface of the mold layer 320. A patterned metal layer 324 is disposed on the mold layer 320 to provide electrical connections between the exposed pillars (including, in some examples, electrical connections among the semiconductor dies 302, 304, 305). External interconnect structures 326 are formed on the patterned metal layer 324. Due to the stacked arrangement, the pillars 310 on the first die 302 are taller than the pillars 312 on the second die 304, which are in turn taller than the pillars 314 on the third die 305, allowing all pillar top surfaces to terminate in the same plane at the surface of the mold layer 320.

In some implementations, the second die 304 is coupled to the first die 302 via a bonding layer 348. In some examples, the bonding layer 348 includes a bonding material such as those discussed above with respect to bonding layer 148 in FIG. 1. In some implementations, the third die 305 is coupled to the second die 304 via a bonding layer 349. In some examples, the bonding layer 349 includes a bonding material such as those discussed above with respect to bonding layer 148 in FIG. 1.

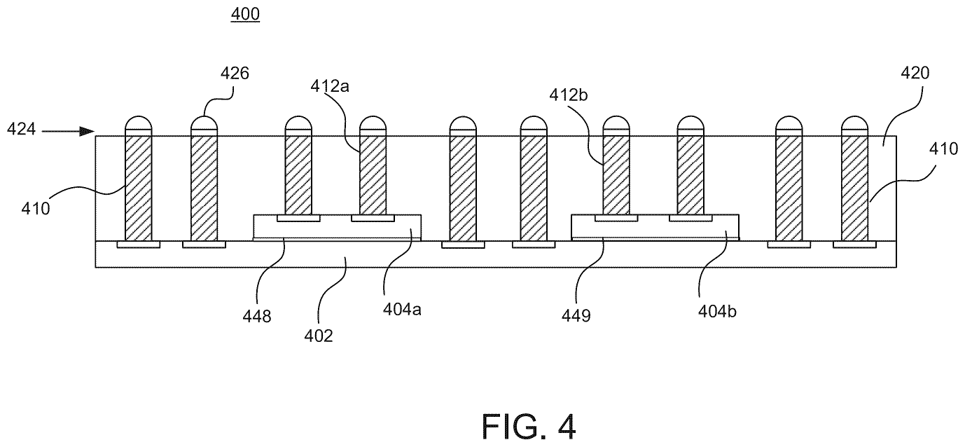

FIG. 4 illustrates a cross-sectional view of another example semiconductor package 400 in accordance with at least one embodiment of the present disclosure. In some implementations, the package 400 includes a lower semiconductor die 402 and two upper semiconductor dies 404a, 404b mounted side-by-side on a die attach region of the lower die 402. A first plurality of pillars 410 is coupled to the lower die 402 and surrounds the upper dies 404a, 404b. A second plurality of pillars 412a is coupled to the upper die 404a, and a third plurality of pillars 412b is coupled to the upper die 404b. A mold layer 420 encapsulates the dies 402, 404a, 404b and their respective pillars, with the top surfaces of all pillars being exposed and substantially coplanar with a planar upper surface of the mold layer 420. A patterned metal layer 424 is disposed on the mold layer 420 to provide electrical connections between the exposed pillars, enabling die-to-die communication between the upper dies 404a and 404b, as well as connections to the lower die 402. External interconnect structures 426 are formed on the patterned metal layer 424. This side-by-side configuration allows for the integration of multiple heterogeneous dies, such as a logic die and a memory die, within a single compact package, creating a system-in-package (SiP) with enhanced functionality.

In some implementations, the upper dies 404a, 404b are coupled to the lower semiconductor die 402 via bonding layers 448, 449. In some examples, the bonding layers 448, 449 include a bonding material such as those discussed above with respect to bonding layer 148 in FIG. 1. In some implementations, the third die 305 is coupled to the second die 304 via a bonding layer 349. In some examples, the bonding layer 349 includes a bonding material such as those discussed above with respect to bonding layer 148 in FIG. 1.

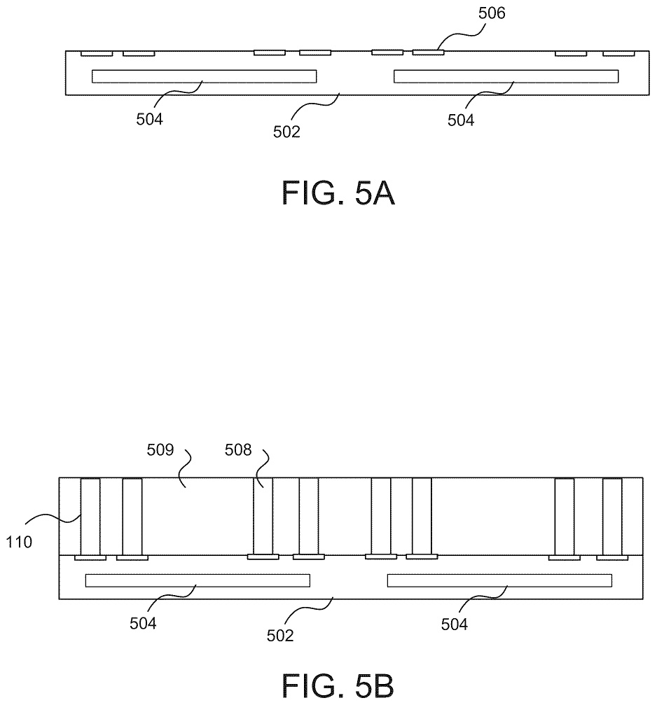

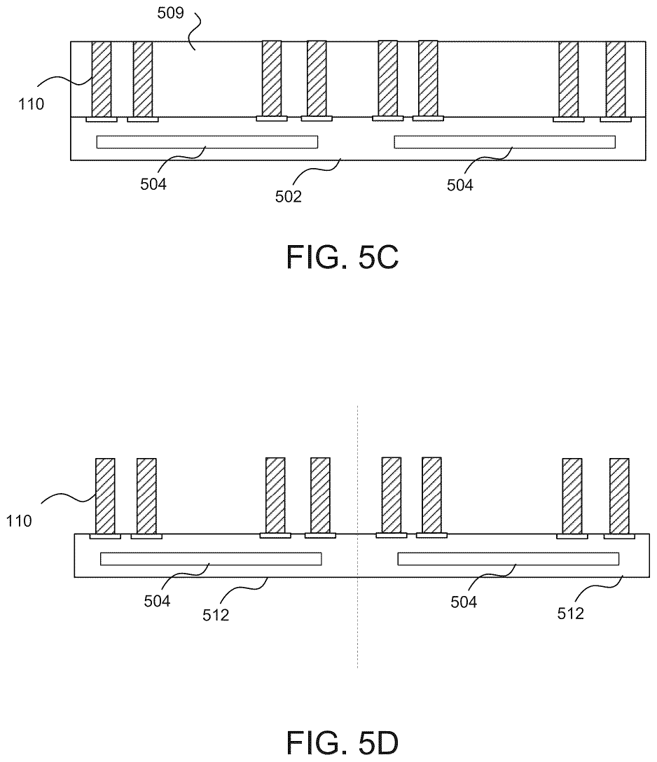

FIGS. 5A-5D illustrate the processing of a semiconductor wafer 502 that can produce the semiconductor die 104 of FIG. 1 in accordance with at least one embodiment of the present disclosure. In some implementations, as shown in FIG. 5A, the wafer 502 includes a plurality of device regions 504 that include one or more integrated circuit elements configured to provide electronic functionality. In various examples, the device regions 504 can implement a logic device such as a processor or controller die, a memory device such as a DRAM or NAND flash die, a sensor die such as an image or pressure sensor, a power semiconductor die such as a MOSFET, IGBT, or diode, and so forth. The wafer 502 includes contact pads 506 providing electrical connection to the device region 504, an RDL structure, and/or a back end of line (BEOL) structure. In some examples, the semiconductor wafer comprises a silicon wafer, a silicon carbide wafer, a gallium nitride wafer, or a gallium arsenide wafer. In some examples, the wafer can include a silicon-on-insulator (SOI) substrate or a glass or sapphire substrate suitable for RF or optoelectronic applications.

In some implementations, a dielectric passivation layer is formed over the wafer surface to protect underlying metallization. The passivation layer can include one or more dielectric materials such as silicon nitride, silicon oxide, or a polyimide layer. In some examples, the passivation layer is patterned to expose the contact pads 506.

With reference to FIG. 5B, a mask layer 509 is formed to provide a template for pillar formation. In some implementations, a seed metal layer is deposited over the exposed contact pads 506 to provide an electroplating base. The seed layer can include a thin film of copper, nickel, titanium, or combinations thereof. In some examples, a barrier or adhesion layer, such as titanium tungsten (TiW), chromium, or tantalum nitride (TaN), is deposited prior to the seed layer to enhance adhesion or to inhibit metal diffusion. In some implementations, a photoresist layer is applied and patterned to define openings 508 corresponding to pillar locations. The thickness of the photoresist layer can be selected to correspond to the desired pillar height. In some examples, a negative-tone photoresist or a dry film resist may be used to achieve a high aspect ratio opening.

With reference to FIG. 5C, pillars 510 are formed in the openings 508. In some implementations, a metal is electroplated into the patterned openings to form the pillars. In some examples, the metal comprises copper, nickel, tin, silver, gold, or an alloy thereof. In other examples, a jacketed pillar structure is formed, such as a copper core surrounded by a nickel or nickel-palladium outer layer to enhance solder wettability or to control intermetallic growth during subsequent joining processes.

The pillars 510 are formed with a height h1 and can be formed with a desired cross-sectional geometry selected to optimize electrical, thermal, or mechanical performance. In some examples, the pillar has a generally cylindrical shape with a uniform diameter along its height. In other examples, the pillar may have a tapered or frustoconical shape, with a base diameter larger than a top diameter to improve mechanical adhesion and stress distribution. In still other examples, the pillar has a rectangular, hexagonal, or other polygonal cross-section corresponding to the lithographically defined pattern. In some implementations, the aspect ratio of the pillar (height-to-diameter) is selected based on the intended interconnect application. In some examples, the pillar height h1 ranges from about 50 μm to 100 μm. In some examples, the pillar diameter ranges from about 10 μm to 80 μm.

With reference to FIG. 5D, in some implementations, after plating the photoresist layer is stripped, leaving the pillars 510. In some examples, a wet etchant selective to copper or nickel may be used. The wafer 502 is singulated to form semiconductor dies 512 that correspond to the semiconductor die 104 in FIG. 1. In some implementations, the wafer is singulated into individual dies or device units by performing a dicing process along predefined separation lanes. In some examples, the wafer is positioned on a dicing tape or other support film, and a cutting tool is translated along the intended cut paths to separate adjacent device regions. In some implementations, dicing is performed using a mechanical sawing system equipped. In other examples, dicing is carried out using a laser, plasma, or stealth dicing process to reduce mechanical stress and minimize chipping of the mold or wafer material.

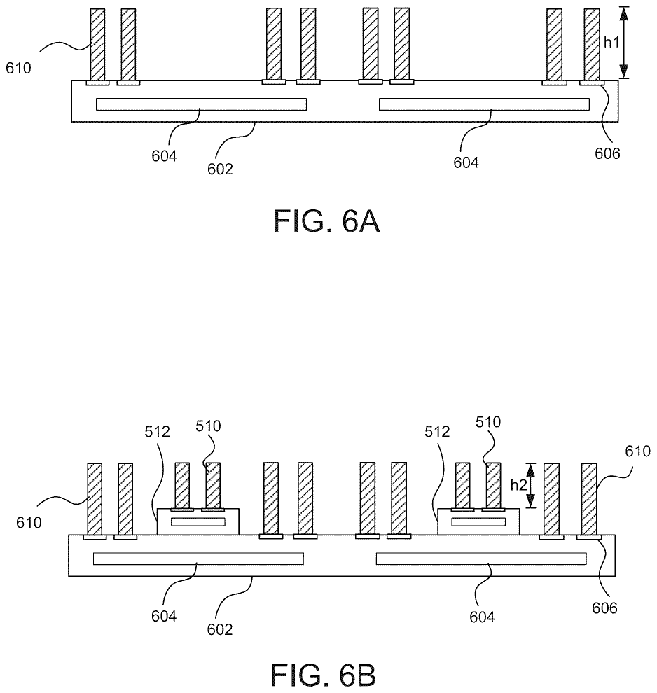

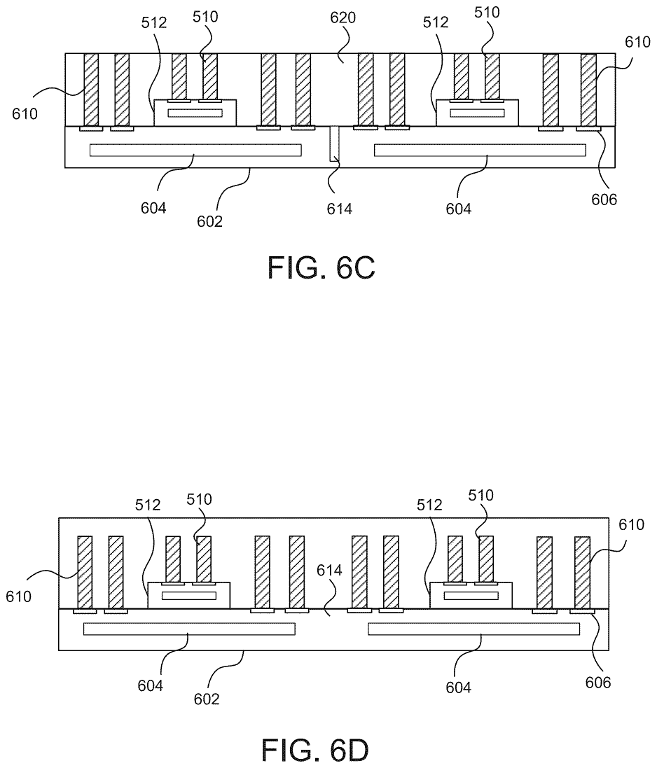

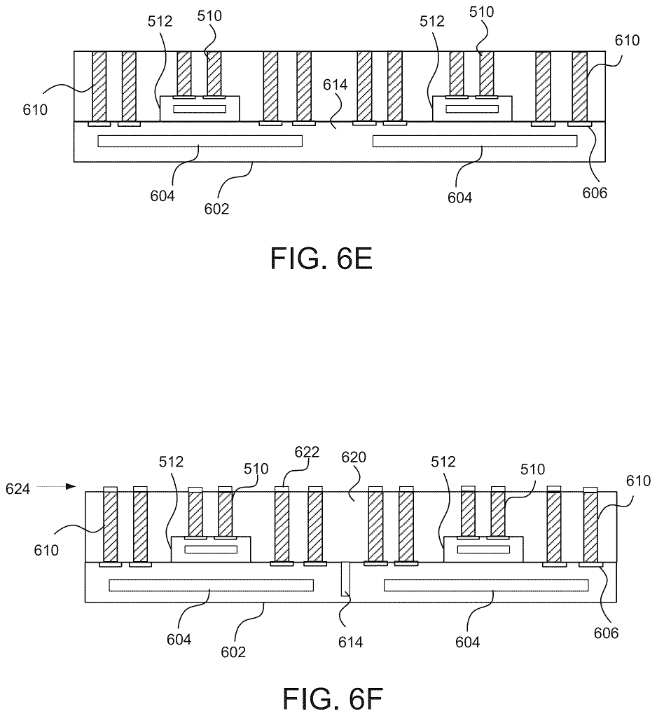

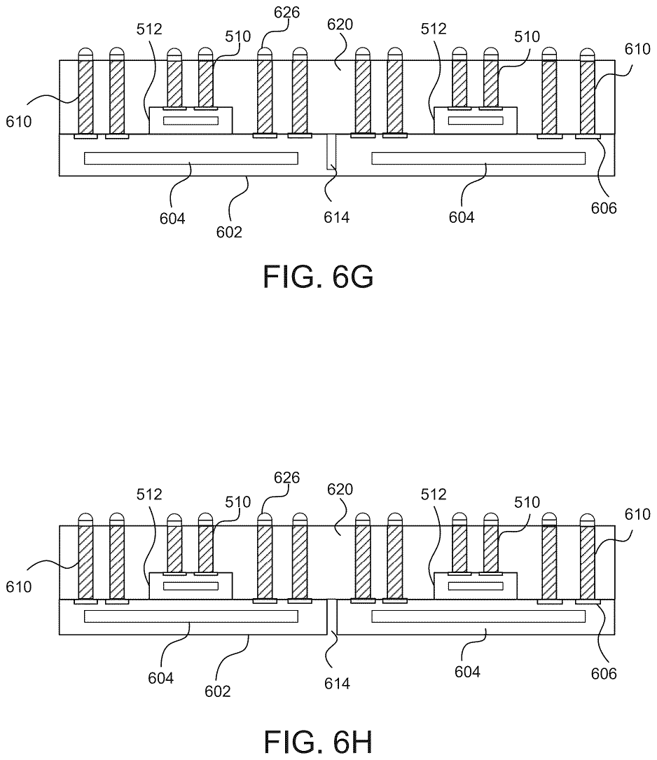

FIGS. 6A-6I illustrate an example process that can be used to fabricate the example package 100 of FIG. 1. In FIG. 6A, a semiconductor wafer 602 is provided. For example, the semiconductor wafer 602 includes the device regions 604 that form the bottom semiconductor die. For example, the device regions 604 that include one or more integrated circuit elements configured to provide electronic functionality. In various examples, the device regions 604 can implement a logic device such as a processor or controller die, a memory device such as a DRAM or NAND flash die, a sensor die such as an image or pressure sensor, a power semiconductor die such as a MOSFET, IGBT, or diode, and so forth. The wafer 602 includes contact pads 606 providing electrical connection to the device region 604, an RDL structure, and/or a back end of line (BEOL) structure. In some examples, the semiconductor wafer 602 comprises a silicon wafer, a silicon carbide wafer, a gallium nitride wafer, or a gallium arsenide wafer.

The semiconductor wafer includes pillars 610. In some implementations, pillars 610 are formed through a process similar to the process shown in FIGS. 5A-5C. Thus, a description of the process of forming pillars 610 on the semiconductor wafer 602 is omitted. The pillars 610 are formed with a height h2 that is greater than height h1 of pillars 510. The pillars 610 can be formed with a desired cross-sectional geometry selected to optimize electrical, thermal, or mechanical performance. In some examples, the pillar has a generally cylindrical shape with a uniform diameter along its height. In other examples, the pillar may have a tapered or frustoconical shape, with a base diameter larger than a top diameter to improve mechanical adhesion and stress distribution. In still other examples, the pillar has a rectangular, hexagonal, or other polygonal cross-section corresponding to the lithographically defined pattern. In some implementations, the aspect ratio of the pillar (height-to-diameter) is selected based on the intended interconnect application. In some examples, the pillar height h1 ranges from about 100 μm to 200 μm. In some examples, the pillar diameter ranges from about 10 μm to 80 μm.

With reference to FIG. 6B, the semiconductor dies 512 of FIG. 5D are coupled to the semiconductor wafer 602. As discussed above, the semiconductor wafer 602 includes die attach regions that are free of pillars 610. In some implementations, the die attach regions are each surrounded by pillars 610. In some implementations, where the semiconductor dies 512 includes TSVs, the die attach regions can include contacts for electrically coupling the contacts to the TSVs. In some various implementations, the semiconductor dies 512 can be arranged in a grid or fan-out pattern.

In some implementations, the semiconductor dies 512 are attached to the wafer 602 using a bonding material configured to provide mechanical and, in some cases, electrical connection. In some examples, the bonding material includes a solder, such as tin, tin-silver, or tin-copper, that is reflowed to form a metallurgical joint. In other examples, the bonding material comprises an adhesive layer. In some examples, the adhesive is a conductive adhesive, such as a silver-filled or copper-filled epoxy paste, an anisotropic conductive film (ACF), or an anisotropic conductive paste (ACP), providing both mechanical and electrical coupling. In other examples, the adhesive is a non-conductive adhesive, such as an epoxy, polyimide, or silicone-based film or paste.

In some implementations, a barrier or metallization layer may be provided on the die and/or wafer surfaces before bonding to improve adhesion and prevent interdiffusion. In some examples, the barrier layer includes nickel, titanium, or platinum deposited by sputtering, evaporation, or electroless plating. In some implementations, after the die is attached, the assembly may be subjected to a curing or reflow process to strengthen the bond and improve reliability. In some examples, a thermal cure is performed between approximately 150° C. and 250° C. depending on the adhesive composition.

In some implementations, as shown in FIG. 6C, the semiconductor wafer 602 is partially sawn or scored along predefined dicing lanes to facilitate subsequent singulation of individual dies or device regions. The partial sawing process defines mechanical separation grooves 614, or dicing lanes, without fully severing the wafer, allowing further processing to occur while maintaining wafer integrity. In some implementations, the device regions of the semiconductor wafer 602 are arranged in a grid pattern, each region corresponding to a die location, and the partial sawing is performed based on the grid pattern. In some examples, sawing can be carried out using a cutting tool that is translated along predefined scribe or dicing streets separating adjacent device regions. In other examples, a laser or plasma dicing system can be used to ablate or locally weaken the wafer material along the desired cut paths. In some implementations, the partial sawing process removes only a portion of the wafer thickness to leave a remaining base layer that holds the semiconductor wafer 602 together during subsequent processing. In some examples, the saw depth is controlled to extend between approximately 30% and 80% of the wafer thickness. In other examples, the saw depth is adjusted based on wafer material properties, die thickness, and so on.

After partial sawing, the wafer remains as a single composite structure suitable for additional processing steps. The partial sawing process enables controlled die separation after all wafer-level processing has been completed, reducing mechanical stress and improving edge quality of the resulting package.

With reference to FIG. 6D, a mold layer 620 is formed over the semiconductor wafer 602 to encapsulate the metal pillars and the attached semiconductor die 512. The mold layer 620 provides mechanical protection, environmental sealing, and structural support during subsequent wafer-level processing and singulation. In some implementations, the mold layer 620 is deposited, dispensed, or molded across the wafer surface such that the material fills gaps between adjacent pillars and around the sidewalls of the dies. In some examples, the mold layer is applied using a compression molding process in which a curable molding compound is pressed against the stack under heat and pressure. In other examples, the mold layer 620 is formed by dispensing or spin-coating a liquid encapsulant that is subsequently cured to a solid state.

In some implementations, the mold material of the mold layer 620 comprises a polymeric or resin-based compound having mechanical and thermal properties suitable for semiconductor packaging. In some examples, the mold layer 620 includes an epoxy molding compound (EMC) filled with silica or alumina particles to control coefficient of thermal expansion and improve dimensional stability. In other examples, the mold layer 620 includes a silicone, polyimide, or other dielectric material compatible with wafer-level processes.

With reference to FIG. 6E, the mold layer 620 is planarized to expose the top surfaces of the pillars 510, 610. The planarization process removes a controlled thickness of the mold material until the upper surfaces of the pillars are substantially coplanar with the surrounding mold surface. In some examples, the planarization is performed by mechanical grinding or lapping using an abrasive pad or slurry to achieve the desired level of exposure. In other examples, a combination of grinding and chemical-mechanical polishing (CMP) is employed to refine surface planarity and minimize topography variation across the wafer.

With reference to FIG. 6F, a patterned metal layer 624 including metal pads 622 and traces is formed over the planarized mold surface to electrically connect the exposed pillars and provide external contact regions for the package. In some examples, a seed layer such as copper, titanium, or titanium-copper is deposited by sputtering, evaporation, or electroless plating to enable subsequent metallization. A photoresist is applied and patterned to define interconnect geometries, and a conductive material, such as copper, nickel, gold, aluminum, or combinations thereof, is deposited by electroplating or electroless plating, for example, to form the pads 622 and traces. A single layer of metal routing can be used to connect the pillars 510 of the top die 512 to the pillars 610 of semiconductor wafer 602, thus obviating the need for complex multilevel RDL structures. However, in some implementations, the patterned metal layer 624 may be a layer of a multilevel RDL structure, with multiple metal and dielectric layers formed sequentially for multilevel routing. In some implementations, the pads on the mold surface are configured to receive external interconnects such as solder bumps, copper pillars, or wire bonds.

In some implementations, instead of using photolithographic patterning, conductive pads 622 and traces are formed on the mold surface by a direct copper writing or additive deposition process. In some examples, the process includes dispensing or jetting a copper-containing ink or nanoparticle formulation along programmed trace paths, followed by curing or sintering to form conductive lines and copper pads. In other examples, an additive manufacturing system deposits copper or other conductive material by laser-induced or aerosol-jet printing directly onto the mold surface without the use of a photoresist mask. In some implementations, the directly written copper traces are electrically connected to the exposed metal pillars and define routing paths between the pillars and external contact sites. In some examples, additional layers of conductive material may be sequentially written to increase line thickness or current-carrying capacity. In other examples, a protective or dielectric overcoat is subsequently applied to encapsulate and insulate the written traces.

With reference to FIG. 6G, in some implementations, solder material is applied to the metal pads formed over the mold surface to create interconnect structures 626 such as microbumps or ball grid array (BGA) solder balls. In some examples, a solder paste is deposited onto the pads 622 using a stencil or screen printing process, with stencil apertures defining the bump pattern and volume. In other examples, solder is applied by jet printing, dispensing, or placement of pre-formed solder spheres onto the pads.

In some implementations, reflow process after solder deposition is used to melt and re-shape the solder material, forming discrete bumps on the pad surfaces. In some implementations, the resulting solder bumps form microbumps suitable for fine-pitch interconnects. In some examples, the microbumps have diameters less than about 50 μm. In other implementations, the solder bumps form ball grid array (BGA) structures suitable for attachment of the wafer or die assembly to a package substrate or printed circuit board. In some examples, BGA solder balls have diameters between approximately 100 μm and 500 μm and are arranged in a grid or peripheral array pattern.

In some implementations, as shown in FIG. 6H, the semiconductor wafer 602 is thinned from its back surface to a desired thickness using a backgrinding process. For example, backgrinding may be performed to reduce overall package height, improve thermal performance, or facilitate subsequent singulation. In some implementations, the final wafer thickness is selected based on mechanical stability and package design requirements. In some examples, the wafer is thinned to a thickness between approximately 100 μm and 200 μm. In some implementations, the semiconductor wafer 602 is thinned until previously formed grooves or partial saw cuts are exposed, thereby defining individual dies or device regions for singulation. For example, the thinning process may be terminated upon reaching the depth of the previously formed scoring or partial sawing lanes.

In some implementations, thinning is performed using a mechanical grinding system equipped with an abrasive wheel or pad. In some examples, a coarse grinding step is followed by one or more fine grinding or polishing steps to achieve a smooth surface finish and controlled final thickness. In other examples, chemical-mechanical polishing (CMP) or plasma etching is used after grinding to remove subsurface damage or stress from the wafer.

With reference to FIG. 6I, wafer assembly is singulated into individual packages 630 by performing a dicing process along predefined separation lanes. In some examples, the wafer is positioned on a dicing tape or other support film, and a cutting tool is translated along the intended cut paths to separate adjacent device regions. In some implementations, the dicing process utilizes previously formed grooves or partial saw cuts as alignment guides for the cutting operation. In some examples, the grooves serve as dicing lanes that define the intended separation boundaries between neighboring dies. In other examples, the grooves provide optical alignment features detectable by a vision system to automatically register the saw blade or laser cutting path with the pre-patterned wafer geometry. In some implementations, dicing is performed using a mechanical sawing system. In other examples, dicing is carried out using a laser, plasma, or stealth dicing process to reduce mechanical stress and minimize chipping of the mold or wafer material.

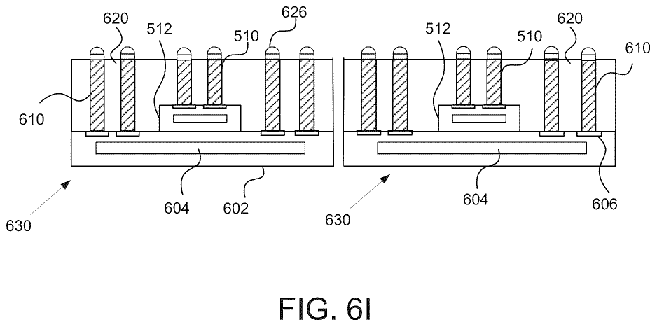

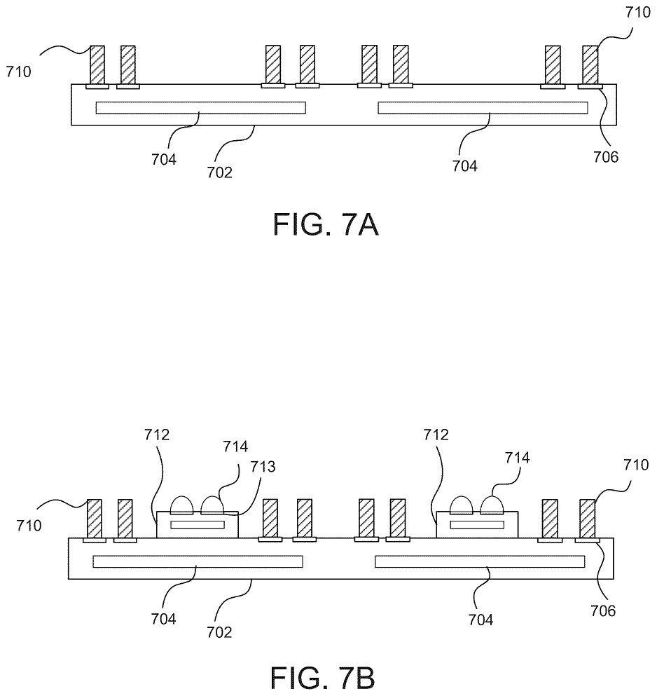

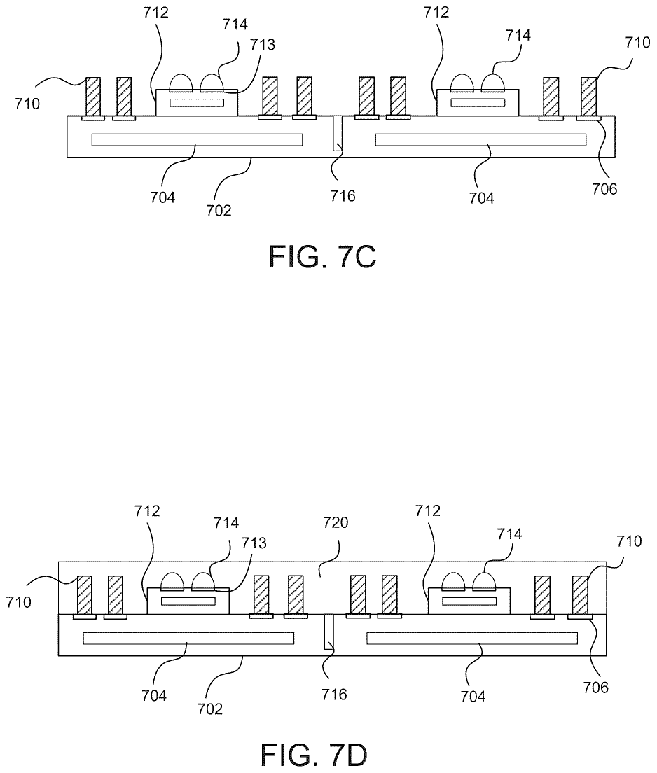

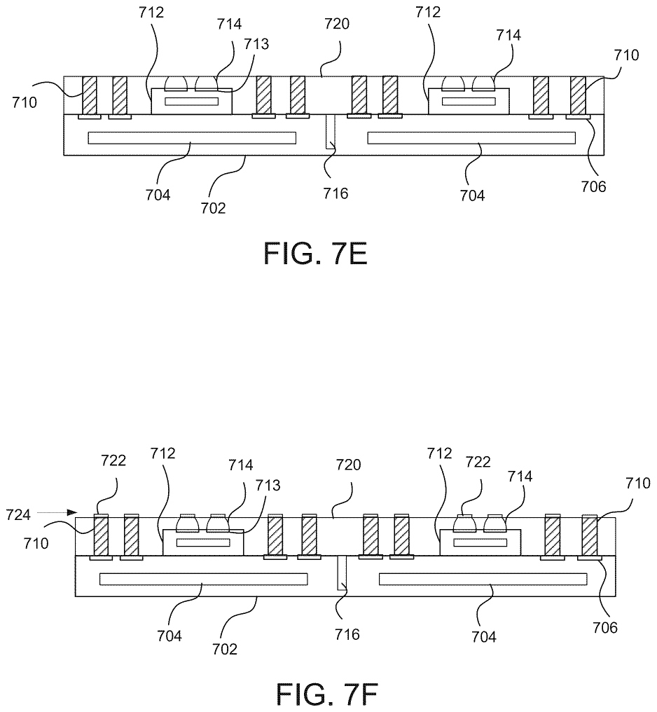

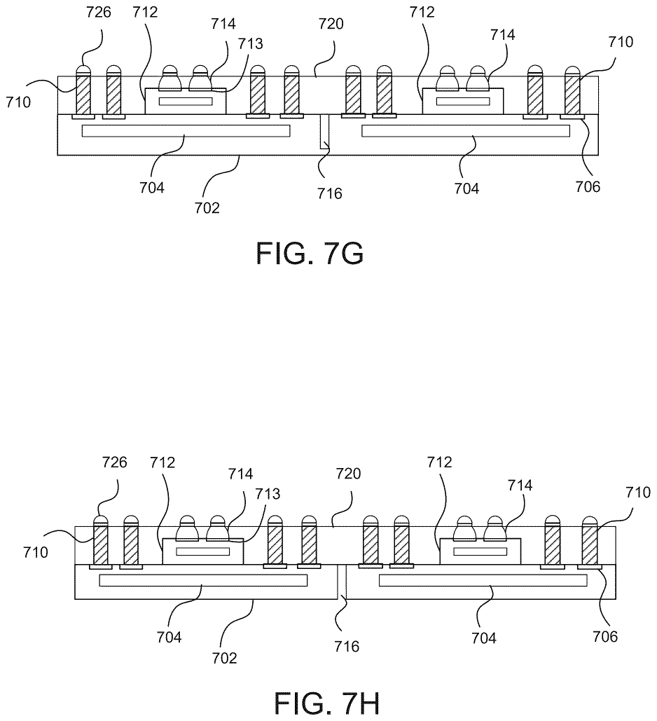

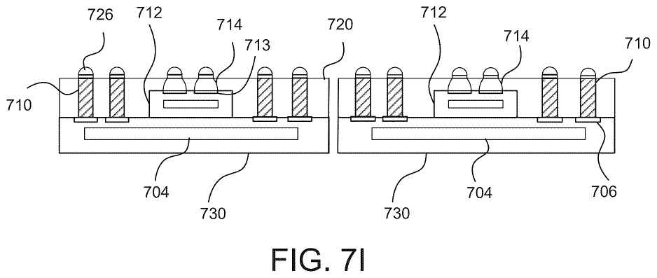

FIGS. 7A-7I illustrate another example process that can be used to fabricate a semiconductor package in accordance with at least one embodiment of the present disclosure. In this embodiment, solder balls are used as the interconnect structures on the upper die instead of pillars. In FIG. 7A, a semiconductor wafer 702 is provided, which is analogous to the wafer 602 described previously. The wafer 702 includes device regions 704 and contact pads 706. A plurality of pillars 710 are formed on the contact pads 706. The pillars 710 are formed through a process similar to that shown in FIGS. 5A-5C, and their height is selected to accommodate the stacked die configuration.

With reference to FIG. 7B, semiconductor dies 712 are coupled to die attach regions on the semiconductor wafer 702. Unlike the dies 512, the semiconductor dies 712 include solder balls 714 as their primary interconnect structures, which are formed on contact pads 713 of the dies 712. In some examples, the solder balls 714 are formed using a solder paste printing and reflow process or by placing pre-formed solder spheres. The semiconductor dies 712 can be attached to the wafer 702 using a bonding material as described in connection with FIG. 6B.

With reference to FIG. 7C, in some implementations, the semiconductor wafer 702 is partially sawn or scored to predefine dicing lanes 716 to facilitate subsequent singulation, in a process analogous to that described for FIG. 6C.

With reference to FIG. 7D, a mold layer 720 is formed over the semiconductor wafer 702 to encapsulate the pillars 710, the attached semiconductor dies 712, and the solder balls 714. The mold layer 720 provides mechanical protection and structural support. In some implementations, the mold layer 720 is applied using a compression molding or liquid encapsulant dispensing process, as previously described.

With reference to FIG. 7E, the mold layer 720 is planarized to expose the top surfaces of both the pillars 710 and the solder balls 714. The planarization process, such as mechanical grinding or CMP, removes the mold material until the upper surfaces of the pillars 710 and the solder balls 714 are substantially coplanar with the surrounding mold surface. This creates a uniform, coplanar surface for subsequent metallization, with the ground-down solder balls 714 providing flat, exposed conductive contacts.

With reference to FIG. 7F, a patterned metal layer 724, including metal pads 722 and traces, is formed over the planarized mold surface. This layer provides electrical connections between the exposed top surfaces of the pillars 710 and the solder balls 714, enabling die-to-die communication. The formation process for the patterned metal layer 724 can be similar to that described for layer 624.

With reference to FIG. 7G, external interconnect structures 726, such as BGA solder balls or microbumps, are formed on the metal pads 722. These structures are configured for attaching the finished package to an external component, such as a printed circuit board.

With reference to FIG. 7H, the semiconductor wafer 702 is thinned from its back surface to a desired thickness using a backgrinding process. This step reduces the overall package profile and can expose the previously formed partial saw cuts, as described in connection with FIG. 6H.

With reference to FIG. 7I, the wafer assembly is singulated into individual packages 730 by performing a dicing process along the predefined separation lanes. This final step separates the individual packaged devices, which can then be tested and assembled into electronic systems. This process is analogous to the process described for FIG. 6I.

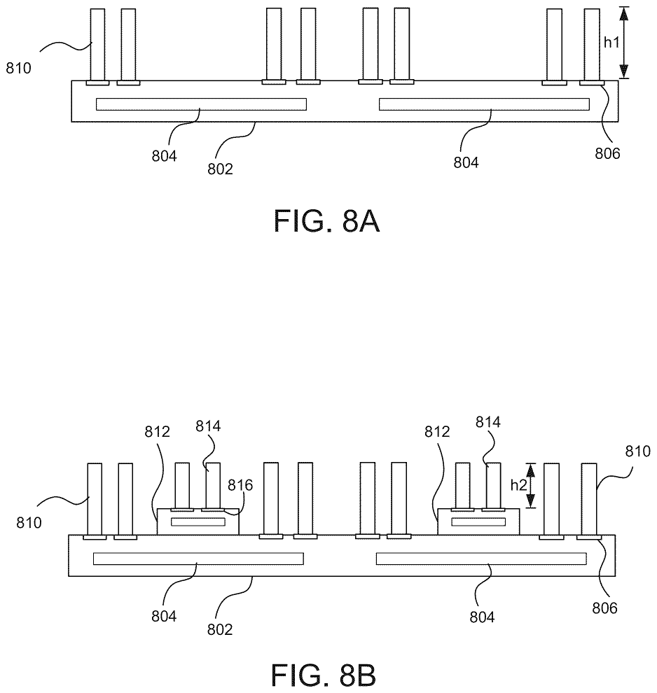

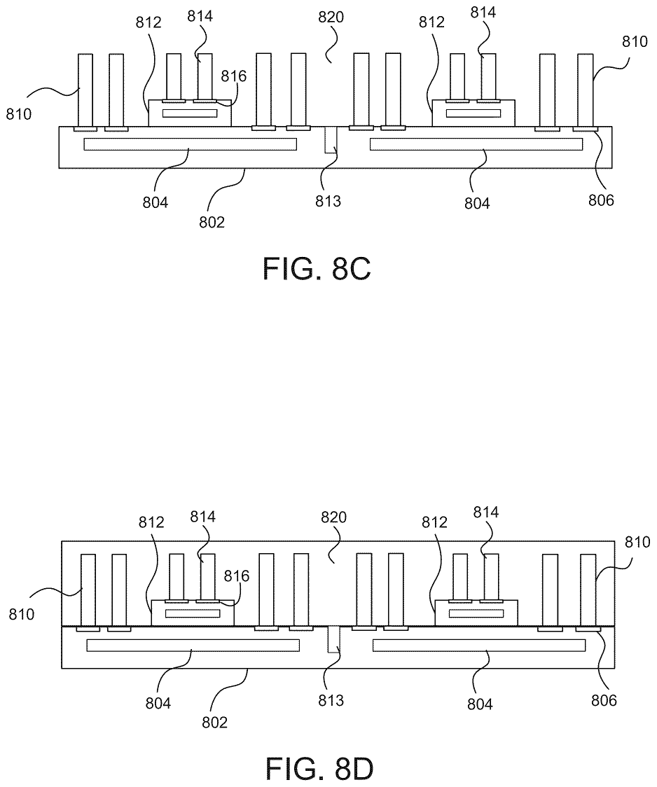

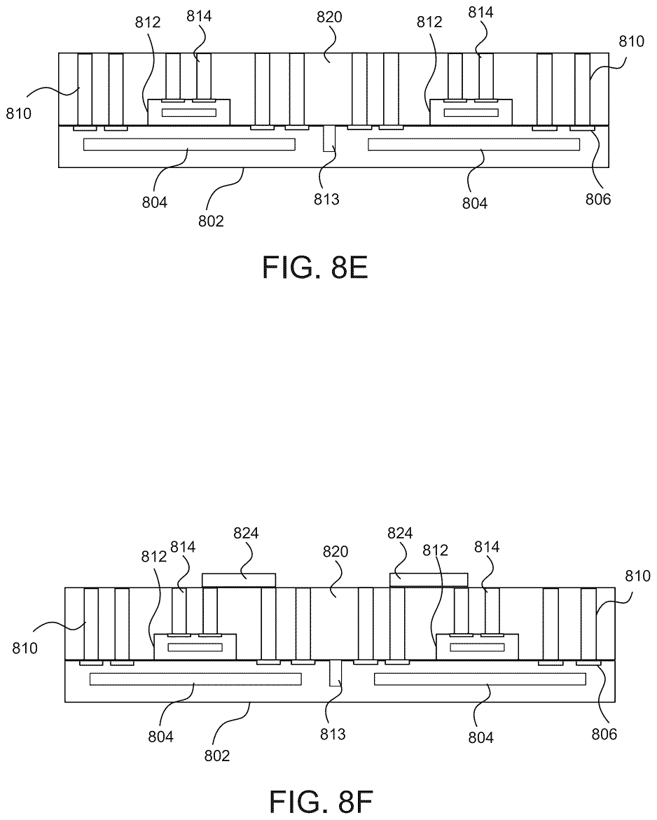

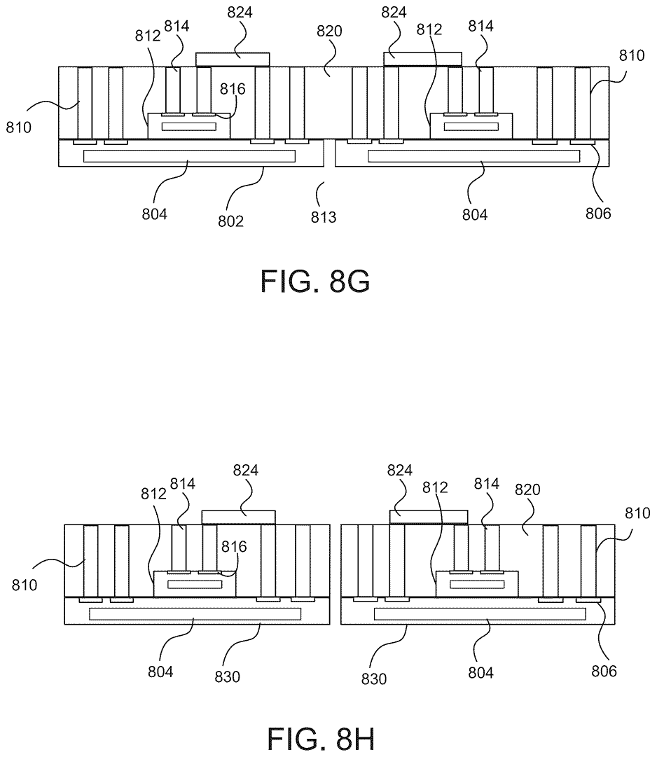

FIGS. 8A-8H illustrate another example process that can be used to fabricate an optoelectronic package in accordance with at least one embodiment of the present disclosure. This process is analogous to the process shown in FIGS. 6A-6I, but is adapted for optical interconnects using optically transmissive pillars instead of electrically conductive metal pillars.

With reference to FIG. 8A, a semiconductor wafer 802 is provided. The wafer 802 can include a plurality of device regions 804, which can include photonic integrated circuits (PICs), laser diodes, photodetectors, modulators, or other optoelectronic devices. The wafer 802 includes optical coupling regions 806, such as the ends of on-chip waveguides or surfaces of active devices, for transmitting or receiving optical signals. A plurality of optically transmissive pillars 810 are formed on the optical coupling regions 806. In some examples, the optically transmissive pillars 810 are formed from a transparent dielectric material such as glass, silicon dioxide, silicon nitride, or a transparent polymer such as SU-8 or polyimide. The optically transmissive pillars 810 can be formed by depositing a layer of the transparent material and patterning it using photolithography and etching, or by direct patterning of a photosensitive polymer. These optically transmissive pillars 810 are configured to act as light pipes or optical vias.

In some implementations, the optically transmissive pillars are defined by coating the wafer with a photo-patternable transparent material and exposing the material to patterned radiation through a lithographic mask. The exposed regions are crosslinked and retained while the unexposed regions are removed during a development process, thereby producing a plurality of transparent pillars having predetermined height and lateral geometry.

In other implementations, the optically transmissive pillars are formed using a molding process. For example, a mold structure having cavities corresponding to the desired pillar geometry is aligned with the wafer, and a liquid transparent material is introduced into the cavities. The material is then cured, for example by ultraviolet radiation or thermal curing, and the mold is removed to release the pillars.

With reference to FIG. 8B, semiconductor dies 812 are coupled to die attach regions on the semiconductor wafer 802. In some implementations, the semiconductor dies 812 also include PICs, laser diodes, photodetectors, modulators, and/or other optoelectronic devices. The semiconductor dies 812 include optical coupling regions 816, such as the ends of on-chip waveguides or surfaces of active devices, for transmitting or receiving optical signals. The dies 812 include their own optically transmissive pillars 814 having a height h1 that is less than the height h2 of the optically transmissive pillars 810 on the wafer 802. The optically transmissive pillars 814 can be fabricated using the same or different processes as optically transmissive pillars 810. The dies 812 are attached to the wafer 802 using a bonding material, such as a transparent adhesive, with precise alignment being critical for subsequent optical coupling.

With reference to FIG. 8C, the semiconductor wafer 802 is partially sawn or scored to predefine dicing lanes 813 to facilitate subsequent singulation, in a process analogous to that described for FIG. 6C.

With reference to FIG. 8D, a mold layer 820 is formed over the semiconductor wafer 802 to encapsulate the optically transmissive pillars 810, 814 and the semiconductor dies 812. In some implementations, the mold material is selected to have a refractive index lower than that of the pillar material to provide optical confinement (cladding) for the light guided within the pillars. In some examples, a standard EMC is used.

With reference to FIG. 8E, the mold layer 820 is planarized to expose the top surfaces of the optically transmissive pillars 810 and 814. The planarization process, such as mechanical grinding or CMP, creates a uniform, coplanar optical interface surface where the tops of all pillars are exposed and coplanar with the surrounding mold surface.

With reference to FIG. 8F, a patterned optical waveguide layer 824 is formed over the planarized mold surface. This layer functions as an optical redistribution layer (O-RDL), routing light signals between the exposed tops of pillars 810 and 814. In some implementations, the waveguide layer 824 is formed by depositing a waveguide core material, such as silicon nitride or a high-index polymer, and patterning it using photolithography and etching to define waveguide paths for die-to-die optical communication.

In some implementations, external optical interface structures (not shown) are formed on or integrated with the waveguide layer 824. These structures are configured to couple light between the package and external components, such as optical fibers. In some examples, the interface structures include grating couplers, micro-lenses, or V-grooves for passive fiber alignment.

With reference to FIG. 8G, the semiconductor wafer 802 is thinned from its back surface to a desired thickness using a backgrinding process. This step is analogous to that described in connection with FIG. 6H.

With reference to FIG. 8H, the wafer assembly is singulated into individual optoelectronic packages 830 by performing a dicing process along the predefined separation lanes. This final step separates the individual packaged devices, which provide a compact, integrated solution for multi-chip optical systems.

Throughout the present disclosure, the lower substrate (e.g., lower semiconductor die 102, 302, 402 or semiconductor wafer 602, 702, 802) has been described primarily as a semiconductor die or wafer containing active electronic or optoelectronic devices. However, the principles of the disclosed packaging architecture are not limited to such configurations. In other implementations, the lower substrate may be a passive component that provides mechanical support and electrical or optical routing without containing active integrated circuits. For example, the lower substrate can be an interposer, such as a silicon interposer with through-silicon vias (TSVs), a glass interposer, or an organic laminate interposer. In other examples, the lower substrate can be a printed circuit board (PCB), a ceramic substrate, or a direct-bonded metal (DBM) substrate. In such cases, the substrate would still include contact pads and the corresponding pillars (e.g., pillars 110, 310, 410, 610, 710, 810) to facilitate interconnection with one or more upper dies according to the methods described herein.

It is to be understood that the various embodiments, configurations, and processes described herein are illustrative and not limiting, and that features from different embodiments can be combined. For example, the three-die stack configuration of FIG. 3 can be fabricated using the process described in FIGS. 7A-7I, wherein one or more of the dies utilize solder balls that are subsequently planarized instead of pre-formed pillars. In another example, the side-by-side die arrangement of FIG. 4 can be adapted to create an optoelectronic package by incorporating the optically transmissive pillars and waveguide layers described in connection with FIGS. 8A-8H. Furthermore, a hybrid electrical-optical package can be formed by integrating both conductive metal pillars and optically transmissive pillars within the same package assembly. The use of a passive interposer or PCB as the lower substrate, as described above, can be applied to any of the multi-die configurations, including the stacked and side-by-side arrangements shown in FIGS. 1, 3, and 4.

Furthermore, it is to be understood that the various semiconductor dies or die wafers described with reference to the figures can share any or all of the characteristics described in connection with the lower semiconductor die 102 and the upper semiconductor die 104 of FIG. 1. For example, any of these dies can be implemented as various types of devices, such as a logic die, a memory die, a sensor die, or a power semiconductor die. Likewise, these dies can comprise various semiconductor materials, including silicon, silicon carbide, gallium nitride, or gallium arsenide, and can have a thinned back surface.

This flexibility enables the creation of highly integrated heterogeneous packages where dies are selected based on function and optimal fabrication technology. In some implementations, a single semiconductor package can include multiple dies that implement different types of components. For example, a processor die can be packaged alongside a high-bandwidth memory die to form a compact system-in-package. Furthermore, these functionally distinct dies can be composed of different materials. For instance, a high-performance logic die fabricated from silicon can be integrated with a power management die fabricated from a wide-bandgap material such as silicon carbide (SiC) or gallium nitride (GaN), all within the same package assembly.

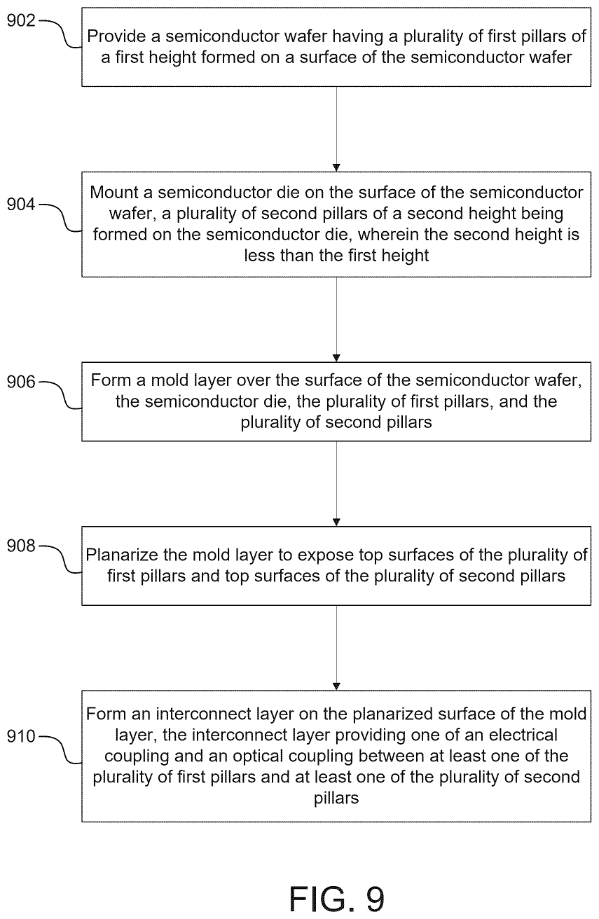

FIG. 9 is a flow chart illustrating an example method for fabricating a semiconductor package in accordance with at least one embodiment of the present disclosure. In some implementations, the method of FIG. 9 is analogous to the process described in FIGS. 6A-6F. In some implementations, the method of FIG. 9 is analogous to the process described in FIGS. 7A-7F. In some implementations, the method of FIG. 9 is analogous to the process described in FIGS. 8A-8F.

The method of FIG. 9 includes, at operation 902, providing a first substrate having a plurality of first pillars of a first height formed on a surface of the first substrate. In some implementations, providing a first substrate includes providing a semiconductor wafer that includes a plurality of metal pillars coupled to contact pads of the semiconductor wafer. In other implementations, where the substrate includes optical electronics such as a photonic integrated circuit, providing a first substrate includes providing a semiconductor wafer that includes a plurality of optically transmissive pillars coupled to optical interfaces (e.g., optical transmitters and/or optical receivers) of the semiconductor wafer. In some examples, the plurality first pillars have height ranging from about 100 μm to 200 μm. In some examples, the plurality first pillars have height of at least 200 μm.

The method of FIG. 9 includes, at operation 904, mounting a semiconductor die on the surface of the first substrate, a plurality of second pillars of a second height being formed on the semiconductor die, wherein the second height is less than the first height. In some implementations, the semiconductor dies include a plurality of metal pillars coupled to contact pads of the semiconductor die. In other implementations, where the die includes optical electronics such as a photonic integrated circuit, the semiconductor die includes a plurality of optically transmissive pillars coupled to optical interfaces (e.g., optical transmitters and/or optical receivers) of the semiconductor die. In some examples, the second pillars have a height in the range of 50 μm to 100 μm. In some examples, mounting the die can include attaching the die via a bonding material such as a solder, sinter material, or an adhesive.

The method of FIG. 9 includes, at operation 906, forming a mold layer over the surface of the first substrate, the semiconductor die, the plurality of first pillars, and the plurality of second pillars. In some implementations, forming a mold layer includes applying an encapsulant to cover the substrate, the mounted die, and the pillars, as shown in FIGS. 6D and 8D.

The method of FIG. 9 includes, at operation 908, planarizing the mold layer to expose top surfaces of the plurality of first pillars and top surfaces of the plurality of second pillars, wherein the exposed top surfaces are substantially coplanar with a planarized surface of the mold layer. In some implementations, planarizing the mold layer includes removing excess mold material from the top of the wafer assembly until the top surfaces of all pillars are exposed, as shown in FIGS. 6E and 8E. This process creates a uniform, coplanar surface across the wafer, with the pillar tops being coplanar with the surrounding mold surface. In some examples, planarization is performed using mechanical grinding, lapping, or chemical-mechanical polishing (CMP).

The method of FIG. 9 includes, at operation, 910, forming an interconnect layer on the planarized surface of the mold layer, the interconnect layer providing one of an electrical coupling and an optical coupling between at least one of the plurality of first pillars and at least one of the plurality of second pillars. In some implementations, forming the interconnect layer includes forming metal traces and pads on the surface of the mold layer. In some examples, a trace connects at least one of the first pillars to at least one of the second pillars, providing an electrical path between the substrate and the die. In some implementations, forming the interconnect layer includes attaching solder structures for electrically coupling the first pillars and/or the second pillars to an external component such as a printed circuit board, interposer, or another package. In other implementations, forming the interconnect layer includes forming an optical waveguide on the surface of the mold layer. In some examples, the optical waveguide optically couples at least one of the first pillars to at least one of the second pillars. In some examples, forming the interconnect layer includes attaching optical couplers for optically coupling the first pillars and/or the second pillars to an external component such as an optical fiber.

The disclosed semiconductor package architecture and fabrication methods provide significant technical advantages over conventional multi-chip packaging technologies. A key advantage lies in the creation of a uniform, coplanar interconnect surface by planarizing the mold layer to expose pillars of varying, pre-adjusted heights. This approach eliminates the need for complex and costly multi-level RDL structures that are typically required to connect dies at different vertical levels. As a result, manufacturing is simplified, reducing the number of lithography, deposition, and etching steps, which in turn can lead to lower production costs and improved yields. The electrical performance is also enhanced, as the single-level patterned metal layer provides shorter, more direct signal paths between dies, reducing parasitic resistance, capacitance, and inductance for improved signal integrity and higher operating speeds. The architecture is flexible, supporting the heterogeneous integration of diverse die types and materials in various stacked or side-by-side configurations, while also enabling effective thermal management through the exposed back surface of the lower substrate.

In some implementations, one or more of the components described herein can be coupled using materials such as, for example, a solder, a sintering (e.g., silver, copper) material, and/or other metal-to-metal type bonding materials. In some implementations, a coupling of components can be performed using, for example, a solder process, a sintering process (e.g., a silver sintering process, a copper sintering process), and/or other metal-to-metal type bonding processes.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, a semiconductor package includes a direct bonded metal (DBM) substrate (e.g., direct bonded copper (DBC)) The DBM substrate can include an insulating layer disposed between a first metal layer and a second metal layer. The insulating layer can be, for example, a ceramic layer. In some implementations, the insulating layer can be or can include, for example, a ceramic material such as alumina (Al2O3) or aluminum nitride (AlN)). In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process. In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material. In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth. In some implementations, the DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

What is claimed is:

1. A semiconductor package, comprising:
a first semiconductor die;
a second semiconductor die coupled to the first semiconductor die;
a plurality of first pillars coupled to the first semiconductor die, the plurality of first pillars having a first height;
a plurality of second pillars coupled to the second semiconductor die, the plurality of second pillars having a second height less than the first height; and
a mold layer encapsulating a surface of the first semiconductor die, the second semiconductor die, the plurality of first pillars, and the plurality of second pillars, wherein top surfaces of the plurality of first pillars and top surfaces of the plurality of second pillars are exposed at and substantially coplanar with a surface of the mold layer.

2. The semiconductor package of claim 1, wherein the plurality of first pillars at least partially surrounds the second semiconductor die.

3. The semiconductor package of claim 1, wherein the plurality of first pillars and the plurality of second pillars include a metal or metal alloy.

4. The semiconductor package of claim 1 further comprising:
a patterned metal layer disposed on the surface of the mold layer, wherein the patterned metal layer is electrically coupled to the top surfaces of the plurality of first pillars and the top surfaces of the plurality of second pillars.

5. The semiconductor package of claim 4, further comprising a plurality of external interconnect structures disposed on the patterned metal layer.

6. The semiconductor package of claim 4, wherein the patterned metal layer electrically couples at least one of the plurality of first pillars to at least one the plurality of second pillars.

7. The semiconductor package of claim 1, wherein the plurality of first pillars and the plurality of second pillars include an optically transmissive material.

8. The semiconductor package of claim 7, wherein the first semiconductor die includes a plurality of first optical interfaces, the plurality of first pillars being disposed on the plurality of first optical interfaces; and
wherein the second semiconductor die includes a plurality of second optical interfaces, the plurality of second pillars being disposed on the plurality of second optical interfaces.

9. The semiconductor package of claim 8 further comprising:
an optical waveguide disposed on the surface of the mold layer, the optical waveguide optically coupling at least one first pillar to at least one second pillar.

10. The semiconductor package of claim 1, further comprising:
a third semiconductor die coupled to the second semiconductor die; and
a plurality of third pillars having a third height less than the second height,
wherein the mold layer further encapsulates the third semiconductor die and the plurality of third pillars, wherein top surfaces of the plurality of third pillars are exposed at and substantially coplanar with the surface of the mold layer.

11. The semiconductor package of claim 1, further comprising:
a third semiconductor die coupled to the first semiconductor die and lateral to the second semiconductor die; and
a plurality of third pillars having a third height less than the first height, wherein the mold layer further encapsulates the third semiconductor die and the plurality of third pillars, wherein top surfaces of the plurality of third pillars are exposed at and substantially coplanar with the surface of the mold layer.

12. A semiconductor package, comprising:
a first semiconductor die having a first substrate material;
a second semiconductor die coupled to the first semiconductor die, the second semiconductor die having a second substrate material different from the first substrate material ;
a plurality of pillars coupled to the first semiconductor die, the plurality of pillars having a first height;
a plurality of interconnects coupled to the second semiconductor die; and
a mold layer encapsulating a surface of the first semiconductor die, the second semiconductor die, the plurality of pillars, and the plurality of interconnects, wherein top surfaces of the plurality of pillars and top surfaces of the plurality of interconnects are coplanar and exposed at a surface of the mold layer.

13. The semiconductor package of claim 12, wherein the first substrate material is one of silicon, silicon carbide, gallium nitride, and gallium arsenide; and wherein the second substrate material is one of silicon, silicon carbide, gallium nitride, and gallium arsenide.

14. The semiconductor package of claim 12, wherein the plurality of interconnects includes conductive pillars.

15. The semiconductor package of claim 12, wherein the plurality of interconnects includes solder structures.

16. The semiconductor package of claim 12, wherein at least one of the first semiconductor die and the second semiconductor die includes a power device die.

17. A method of fabricating a semiconductor package, the method comprising:
providing a semiconductor wafer having a plurality of first pillars of a first height formed on a surface of the semiconductor wafer;
mounting a semiconductor die on the surface of the semiconductor wafer, a plurality of second pillars of a second height being formed on the semiconductor die, wherein the second height is less than the first height;
forming a mold layer over the surface of the semiconductor wafer, the semiconductor die, the plurality of first pillars, and the plurality of second pillars; and
planarizing the mold layer to expose top surfaces of the plurality of first pillars and top surfaces of the plurality of second pillars.

18. The method of claim 17 further comprising:
forming an interconnect layer on a planarized surface of the mold layer, the interconnect layer providing one of an electrical coupling and an optical coupling between at least one of the plurality of first pillars and at least one of the plurality of second pillars.

19. The method of claim 17, further comprising, before forming the mold layer, partially sawing the semiconductor wafer along predefined dicing lanes.

20. The method of claim 19, further comprising thinning the semiconductor wafer from a back surface thereof until grooves formed by the partial sawing are exposed.
